(19) United States
(12) Patent Application Publication
(10) Pub. No.: US 2022/0127721 A1
(43) Pub. Date: Apr. 28, 2022

(54) Depositing Low Roughness Diamond Films

(71) Applicants: Applied Materials, Inc., Santa Clara, CA (US); National University of Singapore, Singapore (SG)

(72) Inventors: Vicknesh Sahmuganathan, Singapore (SG); Zhongxin Chen, Singapore (SG); Gu Jiteng, Singapore (SG); Eswaranand Venkatasubramanian, Santa Clara, CA (US); Loh Kian Ping, Singapore (SG); Abhijit Basu Mallick, Palo Alto, CA (US); John Sudijono, Singapore (SG)

(73) Assignees: Applied Materials, Inc., Santa Clara, CA (US); National University of Singapore, Singapore (SG)

(21) Appl. No.: 17/078,474

(22) Filed: Oct. 23, 2020

(51) Int. Cl. C23C 16/27; H01L 21/02; C23C 16/54; C23C 16/455; C23C 16/511

(52) U.S. Cl. CPC C23C 16/276; C23C 16/279; C23C 16/511; C23C 16/54; C23C 16/45557; H01L 21/02642

(57) ABSTRACT

Methods of depositing a diamond layer are described, which may be used in the manufacture of integrated circuits. Methods include processing a substrate in which nanocrystalline diamond deposited on a substrate, wherein the processing methods result in a nanocrystalline diamond hard mask having high hardness.

### TECHNICAL FIELD

Embodiments of the present disclosure pertain to methods of depositing nanocrystalline diamond films. More particularly, embodiments of the disclosure pertain to deposition of nanocrystalline diamond films during the manufacture of electronic devices, and in particular, integrated circuits (ICs).

### BACKGROUND

As the semiconductor industry introduces new generations of integrated circuits (ICs) having higher performance and greater functionality, the density of the elements that form those ICs is increased, while the dimensions, size, and spacing between the individual components or elements are reduced. While in the past, such reductions were limited only by the ability to define the structures using photolithography, device geometries having dimensions measured in μm or nm have created new limiting factors such as the conductivity of the metallic elements, the dielectric constant of the insulating material(s) used between the elements, or challenges in 3D-NAND or DRAM processes. These limitations may be addressed by more durable and higher hardness hard masks.

A direct way to reduce cost per bit and increase chip density in 3D-NAND is by adding more layers; but a single layer with higher durability and higher hardness would reduce processing time and cost. Traditionally, a very high-quality hard mask film, which has high etch selectivity, high hardness, and high density is used. Current hard mask films include pure, or doped, plasma enhanced chemical vapor deposition (PECVD) amorphous carbon (aC:H) based films based on high hardness and modulus properties, film transparency, and ease in removing after slit etching. PECVD amorphous carbon hard mask films, however, have problems with delamination/peeling at bevels (major issue in downstream etch process), becoming more opaque with thicker films (photo alignment issue), and poor morphology which lead to pillar striations, one sided bowing, and pillar twisting.

Nanocrystalline diamond is known as a high hardness material which can be used as a hard mask in semiconductor device processing. Nanocrystalline diamond hard mask films, while having high hardness and modulus, have high surface roughness, which can lead to diffraction during the lithography of semiconductor processing. Reducing this roughness improves lithographic processes and quality of semiconductor devices processing methods. Accordingly, there is a need for hard masks that have high hardness and modulus, but that have low surface roughness.

### SUMMARY

In one embodiment, a method of depositing a diamond layer on a substrate comprises generating a pulsed plasma in a gas mixture in a substrate processing chamber, the gas mixture comprising a first gas comprising H₂, a second gas comprising CO₂, a third gas selected from the group consisting of CH₄, C₂H₂, and C₂H₄, and a fourth gas comprising an inert gas, and depositing a nanocrystalline diamond layer on the substrate, the nanocrystalline diamond layer having a thickness, a roughness, a hardness, and a modulus.

In other embodiments, a method comprises depositing a diamond layer on a surface of a substrate, the method comprising depositing a nanocrystalline diamond layer having a thickness, a roughness, a hardness, and a modulus using a microwave plasma enhanced chemical vapor deposition process, wherein the roughness is less than 15 nm rms, and the surface of the substrate does not include a nanocrystalline diamond layer under the nanocrystalline diamond layer formed using the microwave plasma enhanced chemical vapor deposition process.

Other embodiments pertain to a non-transitory computer readable medium including instructions, that, when executed by a controller of a substrate processing chamber, causes a substrate processing chamber deposit a diamond layer on a substrate by a method comprising generating a pulsed microwave plasma in a gas mixture in the substrate processing chamber, the gas mixture comprising a first gas comprising H₂ in a range of from 10 to 90 vol. % (e.g., 10 sccm to 96 sccm), a second gas comprising CO₂, a third gas selected from the group consisting of CH₄, C₂H₂, and C₂H₄, and a fourth gas comprising an inert gas selected from the group consisting of helium (He), nitrogen, (N₂), neon (Ne), argon (Ar), and combinations thereof in a range of from 10 sccm to 90 sccm, the third gas and the fourth gas together a range of from 2 to 90 vol. % (e.g., 2 sccm to 10 sccm), and depositing a nanocrystalline diamond layer on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a cross-sectional view of a substrate according to one or more embodiments;

FIG. 1B illustrates a cross-sectional view of a substrate according to one or more embodiments;

FIG. 1C illustrates a cross-sectional view of a substrate according to one or more embodiments;

FIG. 1D illustrates a cross-sectional view of a substrate according to one or more embodiments;

FIG. 2 illustrates a cross-sectional view of a substrate processing chamber according to one or more embodiments; and

FIG. 3 illustrates a flow diagram of a method according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, gallium nitride, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. As an example where a film/layer or partial film/layer has been deposited onto a substrate surface, the exposed surface of the newly deposited film/layer becomes the substrate surface.

As used in this specification and the appended claims, the terms “precursor,” “reactant,” “reactive gas,” and the like are used interchangeably to refer to any gaseous species that can react with the substrate surface.

As used herein, the phrase “nanocrystalline diamond” refers a solid film of diamond typically grown on a substrate, such as silicon. In one or more embodiments, nanocrystallinity is the result of the enhanced re-nucleation reaction in diamond growth, where the growth of diamond crystal is disrupted due to the fluctuation of surrounding environments such as the amounts of radical species, temperature, and pressure. In one or more embodiments, nanocrystalline diamond layers are mainly comprised of small diamond crystals in nanospheres, or a nanocolumnar shape, and amorphous carbon distributed usually distributed in the positions between surrounding crystals or accumulate in the grain boundaries. Nanocrystalline diamond is used as a hard mask material in semiconductor applications because of its chemical inertness, optical transparency, and good mechanical properties.

In one or more embodiments, microwave plasma enhanced chemical vapor deposition (MPECVD) is used to deposit nanocrystalline diamond layers to solve the problem of providing nanocrystalline diamond layers exhibiting both low roughness and high hardness/modulus. In a MPECVD process, a hydrocarbon source, such as a gas-phase hydrocarbon or vapors of a liquid-phase hydrocarbon that have been entrained in a carrier gas, is introduced into a MPECVD chamber. Plasma is then generated or formed in the chamber to create excited CH-radicals. The excited CH-radicals are chemically bound to the surface of a substrate positioned in the chamber, forming the desired nanocrystalline diamond layers thereon. Embodiments described herein in reference to a MPECVD process can be carried out using any suitable thin film deposition system including a microwave plasma source. Examples of suitable systems include the CENTURA® systems which may use a DXZ® processing chamber, PRECISION 5000® systems, PRODUCER® systems, PRODUCER® GT™ systems, PRODUCER® XP Precision™ systems, PRODUCER® SE™ systems, Sym3® processing chamber, and Mesa™ processing chamber, all of which are commercially available from Applied Materials, Inc., of Santa Clara, Calif. Other tools capable of performing MPECVD processes may also be adapted to benefit from the embodiments described herein. In addition, any system enabling the MPECVD processes described herein can be used. Any apparatus description described herein is illustrative and should not be construed or interpreted as limiting the scope of the implementations described herein.

Device manufacturers using a carbon-based hard mask layer demand requirements be met: (1) high selectivity of the hard mask during the dry etching of underlying materials, (2) low film roughness, (3) low film stress, and (4) film strippability. As used herein, the term “dry etching” generally refers to etching processes where a material is not dissolved by immersion in a chemical solution and includes methods such as plasma etching, reactive ion etching, sputter etching, and vapor phase etching.

In one or more embodiments, a nanocrystalline diamond layer is formed on a substrate. The process of one or more embodiments advantageously produces a nanocrystalline diamond layer with high density, high hardness, high etch selectivity, low stress, and excellent thermal conductivity.

Hard masks are used as etch stop layers in semiconductor processing. Ashable hard masks have a chemical composition that allows them to be removed by a technique referred to as ashing once they have served their purpose. An ashable hard mask is generally composed of carbon and hydrogen with trace amounts of one or more dopants (e.g., nitrogen, fluorine, boron, silicon). In a typical application, after etching, the hard mask has served its purpose and is removed from the underlying layer. This is generally accomplished, at least in part, by ashing, also referred to as “plasma ashing” or “dry stripping.” Substrates with hard masks to be ashed, generally partially fabricated semiconductor wafers, are placed into a chamber under vacuum, and oxygen is introduced and subjected to radio frequency power, which creates oxygen radicals (plasma). The radicals react with the hard mask to oxidize it to water, carbon monoxide, and carbon dioxide. In some instances, complete removal of the hard mask may be accomplished by following the ashing with additional wet or dry etching processes, for example when the ashable hard mask leaves behind any residue that cannot be removed by ashing alone.

Hard mask layers are often used in narrow and/or deep contact etch applications, where photoresist may not be thick enough to mask the underlying layer. This is especially applicable as the critical dimension shrinks.

V-NAND, or 3D-NAND, structures are used in flash memory applications. V-NAND devices are vertically stacked NAND structures with a large number of cells arranged in blocks. As used herein, the term “3D-NAND” refers to a type of electronic (solid-state) non-volatile computer storage memory in which the memory cells are stacked in multiple layers. 3D-NAND memory generally includes a plurality of memory cells that include floating-gate transistors. Traditionally, 3D-NAND memory cells include a plurality of NAND memory structures arranged in three dimensions around a bit line.

An important step in 3D-NAND technology is slit etch. As the number of tiers increases in each technology node, to control the slit etch profile, the thickness of the hard mask film has to proportionally increase to withstand high aspect etch profiles. Currently, amorphous carbon (aC:H) films are used due to high hardness and easy to strip after slit etch. However, amorphous carbon hard mask films have delamination at bevel and poor morphology, leading to pillar striations.

In one or more embodiments, nanocrystalline diamond is advantageously used as a hard mask in place of amorphous carbon. Nanocrystalline diamond hard mask films provide high hardness and high modulus, but can result in high levels of surface roughness. Accordingly, in one or more embodiments, provided is a method of processing a substrate in which nanocrystalline diamond is used as a hard mask, wherein processing methods result in a smooth surface.

The processing methods of one or more embodiments advantageously preserve the nanocrystalline diamond hard mask film's hardness and modulus while keeping the surface roughness low. With the nanocrystalline diamond hard mask film's high hardness, high modulus and improved surface roughness, the film can be used as a hard mask to overcome the challenges faced in the amorphous carbon-based films.

In one or more embodiments, to achieve greater etch selectivity, the density and the Young's modulus of the nanocrystalline diamond layer is improved. One of the main challenges in achieving greater etch selectivity and improved Young's modulus is the high compressive stress of such a film making it unsuitable for applications owing to the resultant high wafer bow. Hence, there is a need for nanocrystalline diamond films with high-density and modulus (e.g., higher sp³ content) with high etch selectivity along with low stress (e.g., <500 MPa).

Embodiments described herein, include improved methods of fabricating nanocrystalline diamond hard mask films with high-density (e.g., >1.8 g/cc), high Young's elastic modulus (e.g., >150 GPa), and low stress (e.g., <−500 MPa). In one or more embodiments, the Young's modulus is measured at room temperature, or at ambient temperature, or at a temperature in the range of from about 22° C. to about 25° C. In one or more embodiments, Young's modulus of the nanocrystalline diamond film may be greater than 250 GPa. In other embodiments, Young's modulus of the nanocrystalline diamond film is greater than 300 GPa, greater than 325 GPa or greater than 350 GPa.

In one or more embodiments, the process chamber used can be any CVD process chamber with a plasma source (e.g. remote, microwave, capacitively coupled plasma (CCP), or inductively coupled plasma (ICP)), such as one of the process chambers described above. In some embodiments, flow rates and other processing parameters described below are for a 300 mm substrate. It should be understood these parameters can be adjusted based on the size of the substrate processed and the type of chamber used without diverging from the embodiments disclosed herein. In specific embodiments, the plasma source is a microwave plasma source to provide a microwave plasma enhanced chemical vapor deposition chamber.

A “substrate surface”, as used herein, refers to any substrate or material surface formed on a substrate upon which film processing can be performed. For example, a substrate surface on which processing can be performed includes materials such as silicon, silicon oxide, silicon nitride, doped silicon, germanium, gallium arsenide, gallium nitride, glass, sapphire, and any other materials such as metals, metal nitrides, metal alloys, and other conductive materials, depending on the application. A substrate surface may also include dielectric materials such as silicon dioxide and carbon doped silicon oxides. Substrates may have various dimensions, such as 200 mm, 300 mm, or other diameter wafers, as well as rectangular or square panes.

The deposition gas can then be activated by a plasma, and in specific embodiments, a microwave plasma, to form an activated deposition gas. The deposition gas can be activated by forming a plasma using a power source. Any power source capable of activating the gases into reactive species and maintaining the plasma of reactive species may be used. For example, radio frequency (RF), direct current (DC), or microwave (MW) based power discharge techniques may be used. The power source produces a source plasma power which is applied to the CVD process chamber with a plasma source (e.g. remote, microwave, CCP, or ICP) to generate and maintain a plasma of the deposition gas. In embodiments which use an RF power for the source plasma power, the source plasma power can be delivered at a frequency of from about 2 MHz to about 170 MHz and at a power level of between 500 W and 12,000 W. Other embodiments include delivering the source plasma power at from about 2,000 W to about 12,000 W. The power applied can be adjusted according to size of the substrate being processed. In one or more embodiments, the microwave plasma is applied as a continuous wave at a power in a range of about 2,000 W to about 12,000 W.

Based on the pressure in the CVD chamber, as well as other factors, ionized species formation will be minimized while radical formation is maximized. Without intending to be bound by theory, it is believed that the nanocrystalline diamond layer should be primarily sp³ bonds rather than sp² bonds. Further, it is believed that more sp³ bonding can be achieved by increasing the number of radical species over ionized species during the deposition of the layer. Ionized species are highly energetic can need more room for movement than radicals. Once activated, the activated deposition gas generated in a first volume is then delivered through a second volume having a second pressure. The second volume can be a second chamber or another confined area between the process volume and the CVD chamber with a plasma source. In one example, the second volume is the connection between the CVD chamber with a plasma source and the process volume.

The deposition gas can then be activated to create an activated deposition gas. The deposition gas can be activated by forming a plasma using a power source. Any power source capable of activating the gases into reactive species and maintaining the plasma of reactive species may be used. The power source produces a source plasma power which is applied to the CVD plasma chamber to generate and maintain a plasma of the deposition gas. In embodiments which use an MW generator for the source plasma power, the source plasma power can be delivered at a frequency of from about 2 MHz to about 170 MHz and at a power level of between 500 W and 12,000 W. Other embodiments include delivering the source plasma power at from about 2,000 W to about 12,000 W. The power applied can be adjusted according to size of the substrate being processed.

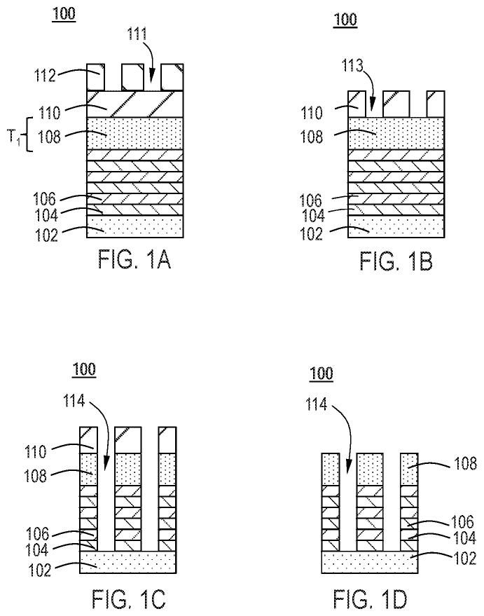

In specific embodiments, the processes described herein can be used to form a nanocrystalline diamond layer on a substrate. FIGS. 1A-1D illustrate schematic cross-sectional views of a substrate 102 at different stages of an integrated circuit fabrication sequence, incorporating a nanocrystalline diamond layer as a hard mask. In FIGS. 1A-1D, the nanocrystalline diamond layer 108 that is deposited has a thickness, T₁, a high modulus (E>250 GPa), a low roughness, and a hardness. In one or more embodiments, the first nanocrystalline diamond layer 108 has a thickness, T₁, in a range of from about 250 nm to about 650 nm. In one or more embodiments, the roughness of the nanocrystalline diamond layer 108, as measured by atomic force microscopy (AFM), is less than 25 nm.

FIG. 1A illustrates a cross-sectional view of a device 100. In one or more embodiments, the device 100 may be a NAND device. The device 100 includes a substrate 102, a plurality of device layers 104, 106, a nanocrystalline diamond layer 108 formed on the plurality of device layers 104, 106.

In one or more embodiments, the substrate 102 can be any semiconducting substrate known in the art, such as monocrystalline silicon, IV-IV compounds such as silicon-germanium (Si—Ge) or silicon-germanium-carbon (Si—Ge—C), III-V compounds, II-VI compounds, epitaxial layers over such substrates, or any other semiconducting or non-semiconducting material, such as silicon oxide, glass, plastic, metal or ceramic substrate. In one or more embodiments, the substrate 102 may include integrated circuits fabricated thereon, such as driver circuits for a memory device (not shown).

In one or more embodiments, the plurality of device layers 104, 106, can be formed over the surface of the substrate 102. The plurality of device layers 104, 106, can be deposited layers which form components of a 3D vertical NAND structure. Components may be formed by all or part of the plurality of device layers (e.g., dielectrics, or discrete charge storage segments). The dielectric portions may be independently selected from any one or more same or different electrically insulating materials, such as silicon oxide, silicon nitride, silicon oxynitride, or other high-k insulating materials. In one embodiment, the structure can comprise silicon oxide/silicon nitride pairs deposited in an alternating fashion. The pairs can be between 100 and 600 Å in total height. The number of pairs can be greater than 10 pairs, such as 32 pairs, 64 pairs or greater.

In some embodiments, an anti-reflective coating 110 is on the nanocrystalline diamond layer 108, and a photoresist 112 is on the anti-reflective coating 110. In some embodiments, the anti-reflective coating 110 is a dielectric anti-reflective coating (DARC). Referring to FIG. 1B, the anti-reflective coating 110 is patterned for form openings 113 that expose portions of a top surface of the nanocrystalline diamond layer 108.

With reference to FIGS. 1C and 1D, the device 100 comprises a channel 114. The channel 114 is formed through the nanocrystalline diamond layer 108 and the plurality of device layers 104, 106. The channel 114 can be substantially perpendicular to a top surface of the substrate 102. For example, the channel 114 may have a pillar shape. The channel 114 can extend substantially perpendicularly to the top surface of the substrate 102. In some embodiments, the channel 114 may be a filled feature. In some other embodiments, the channel 114 may be hollow. In such embodiments, an insulating fill material (not illustrated) may be formed to fill the hollow part surrounded by the channel 114. The insulating fill material may comprise any electrically insulating material, such as silicon oxide, silicon nitride, silicon oxynitride, or other high-k insulating materials.

Referring to FIG. 1D, in one or more embodiments, after the channel 114 is formed, the anti-reflective coating 110 may be removed. Any suitable semiconductor materials can be used for the channel 114, for example silicon, germanium, silicon germanium, or other compound semiconductor materials, such as III-V, II-VI, or conductive or semi-conductive oxides, or other materials. The semiconductor material may be amorphous, polycrystalline or single crystal. The semiconductor channel material may be formed by any suitable deposition methods. For example, in one embodiment, the semiconductor channel material is deposited by low pressure chemical vapor deposition (LPCVD). In other embodiments, the semiconductor channel material may be a recrystallized polycrystalline semiconductor material formed by recrystallizing an initially deposited amorphous semiconductor material.

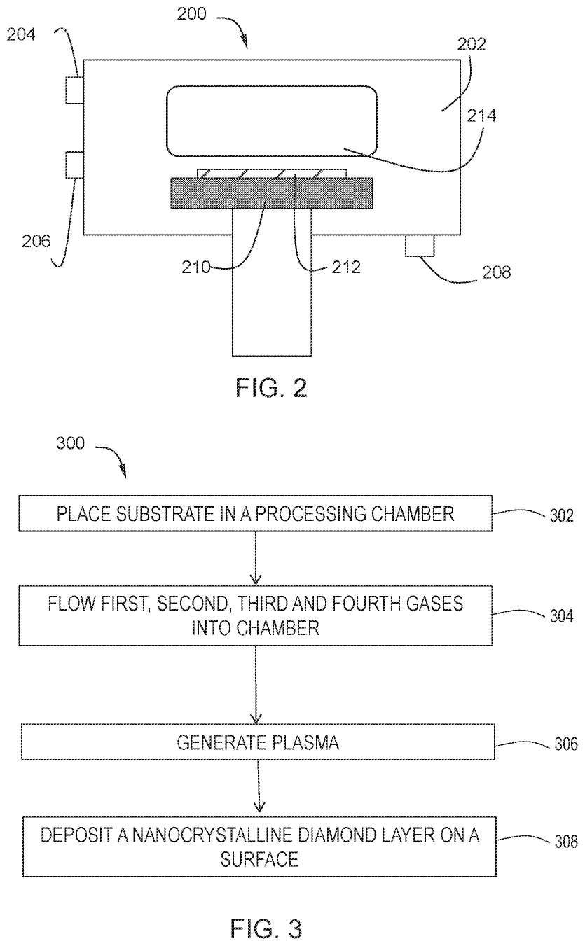

The methods described herein can be performed in a substrate processing chamber 200 as shown in FIG. 2, which is shows the substrate processing chamber 200 including a substrate support 210, which can be a pedestal, such as a rotating pedestal. At least one process cage input 204 is provided to input one or more process gases to the processing chamber interior volume 202. A plasma power source 206 inputs power into the chamber, which generates a plasma 214 in the interior volume 202 of the processing chamber 208. In specific embodiments, the plasma power source 206 is a microwave plasma power source. Gases exit the chamber through pump outlet 2028.

Referring now to FIG. 3, a method 300 of depositing a diamond layer on a substrate comprises at 302 placing a substrate as described herein in a substrate processing chamber, for example, a plasma enhanced chemical vapor deposition chamber. At 304, the method comprises flowing first, second third and fourth gases into the interior volume of substrate processing chamber to provide a gas mixture. At 304, a plasma is generated. Generating the plasma can include generating a pulsed plasma in the gas mixture in the substrate processing chamber. In one or more embodiments, the gas mixture comprises a first gas comprising H₂, a second gas comprising CO₂, a third gas selected from the group consisting of CH₄, C₂H₂ and C₂H₄ and a fourth gas comprising an inert gas. At 308, the method includes depositing a nanocrystalline diamond layer on the substrate, the nanocrystalline diamond layer having a thickness, a roughness, a hardness, and a modulus.

In one or more embodiments, the inert gas is selected from the group consisting of helium (He), nitrogen, (N₂), neon (Ne), argon (Ar), and combinations thereof. In a specific embodiment, the gas mixture comprises H₂ in a range of from 10 volume percent (vol. %) to 90 vol. %, e.g., 10 sccm to 96 sccm, the third gas and the fourth gas together a range of from 2 vol. % to 10 vol. % (e.g., 2 sccm to 10 sccm), and argon in a range of from 10 vol. % to 90 vol. % (e.g., 10 sccm to 90 sccm). In another specific embodiment, the gas mixture comprises H₂ in a range of from 20 to 80 vol. % (e.g., 20 sccm to 80 sccm), the third gas and the fourth gas together a range of from 3 to 8 vol. % (e.g., 3 sccm to 8 sccm), and argon in a range of from 20-80 vol. % (e.g., 20 sccm to 80 sccm). In another specific embodiment, the gas mixture comprises H₂ in a range of from 30-70 vol. % (e.g., 30 sccm to 70 sccm), the third gas and the fourth gas together a range of from 4 to 6 vol. % (e.g., 4 sccm to 6 sccm), and argon in a range of from 30 to 70 vol. % (e.g., 30 sccm to 70 sccm).

In any of the embodiments described immediately above, generating the pulsed plasma in the gas mixture in the substrate processing chamber occurs using a microwave plasma at a peak power in a range of from 2,000 W to 12,000 W, which is pulsed in a range of from 10% to 90% of the peak power at a frequency in a range of from 10 Hz to 300 Hz. In alternative embodiments, generating the pulsed plasma in the gas mixture in the substrate processing chamber occurs using a microwave plasma at a peak power range of from 3,000 W to 9,000 W, which is pulsed in a range of from 25%-80% of the peak power at a frequency in a range of from 40 Hz to 270 Hz.

In any of the embodiments described above, the gas mixture in the substrate processing chamber is at a pressure in a range of from 0.1 Torr to 1.0 Torr. In alternative embodiments, the gas mixture in the substrate processing chamber is at a pressure in a range of from 0.2 Torr to 0.8 Torr.

In any of the embodiments described above, the gas mixture in the substrate processing chamber is at a temperature in a range of from 450° C. to 600° C. In alternative embodiments, the gas mixture in the substrate processing chamber is at a temperature in a range of from 500° C. to 550° C.

In one or more embodiments, the method advantageously form a nanocrystalline diamond layer where the roughness of the nanocrystalline diamond layer is less than 25 nm rms, less than 24 nm rms, less than 23 rms, less than 22 rms, less than 21 nm rms, less than 20 rms, less than 19 rms, less than 18 rms, less than 17 rms, less than 16 rms, less than 15 nm rms, less than 14 nm rms, less than 13 nm rms, less than 12 nm rms, less than 10 nm rms, less than 9 nm rms and greater than 0.5 nm rms.

In specific embodiments, the nanocrystalline diamond layer is formed on a substrate surface that does not include an underlying nanocrystalline diamond layer. In some embodiments, the nanocrystalline diamond layer formed by the plasma enhanced CVD process is a single layer, or the single layer is not formed on an underlying nanocrystalline diamond layer.

The substrate processing chamber can be controlled by a controller. The disclosure provides that the methods described herein may generally be stored in the memory as a software routine that, when executed by a controller or a processor, causes the process chamber to perform processes of the present disclosure. The software routine may also be stored and/or executed by a second controller or processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the controller or processor, transforms the general purpose computer into a specific purpose computer (controller) that controls the chamber operation such that the methods described herein are performed.

The controller or processor can include a non-transitory computer readable medium including instructions, that, when executed by a controller of a substrate processing chamber, causes a substrate processing chamber deposit a diamond layer on a substrate by a method comprising generating a pulsed microwave plasma in a gas mixture in the substrate processing chamber, the gas mixture comprising a first gas comprising H₂ in a range of from 10 to 90 vol. % (e.g., 10 sccm to 96 sccm), a second gas comprising CO₂, a third gas selected from the group consisting of CH₄, C₂H₂, and C₂H₄, and a fourth gas comprising an inert gas selected from the group consisting of helium (He), nitrogen, (N₂), neon (Ne), argon (Ar), and combinations thereof in a range of from 10 to 90 vol. % (e.g., 10 sccm to 90 sccm), the third gas and the fourth gas together a range of from 2 to 90 vol % (e.g., 2 sccm to 10 sccm); and depositing a nanocrystalline diamond layer on the substrate.

In the foregoing specification, embodiments of the disclosure have been described with reference to specific exemplary embodiments thereof. It will be evident that various modifications may be made thereto without departing from the broader spirit and scope of the embodiments of the disclosure as set forth in the following claims. The specification and drawings are, accordingly, to be regarded in an illustrative sense rather than a restrictive sense.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of depositing a diamond layer on a substrate, the method comprising:
generating a pulsed plasma in a gas mixture in a substrate processing chamber, the gas mixture comprising a first gas comprising H₂, a second gas comprising CO₂, a third gas selected from the group consisting of CH₄, C₂H₂, and C₂H₄, and a fourth gas comprising an inert gas; and
depositing a nanocrystalline diamond layer on the substrate, the nanocrystalline diamond layer having a thickness, a roughness, a hardness, and a modulus.

2. The method of claim 1, wherein the inert gas is selected from the group consisting of helium (He), nitrogen, (N₂), neon (Ne), argon (Ar), and combinations thereof.

3. The method of claim 1, wherein the gas mixture comprises:
H₂ in a range of from 10 vol. % to 90 vol. %;
the third gas and the second gas together in a range of from 2 vol. % to 10 vol. %; and
argon in a range of from 10 vol. % to 90 vol. %.

4. The method of claim 1, wherein the gas mixture comprises:
H₂ in a range of from 20 vol. % to 80 vol. %;
the third gas and the second gas together in a range of from 3 vol. % to 8 vol. %; and
argon in a range of from 20 vol. % to 80 vol. %.

5. The method of claim 1, wherein the gas mixture comprises:
H₂ in a range of from 30 vol. % to 70 vol. %;
the third gas and the second gas together in a range of from 4% to 6%; and
argon in a range of from 30 vol. % to 70 vol. %.

6. The method of claim 3, wherein generating the pulsed plasma in the gas mixture in the substrate processing chamber occurs using a microwave plasma at a peak power in a range of from 2,000 W to 12,000 W, which is pulsed in a range of from 10% to 90% of the peak power at a frequency in a range of from 10 Hz to 300 Hz.

7. The method of claim 1, wherein generating the pulsed plasma in the gas mixture in the substrate processing chamber occurs using a microwave plasma at a peak power range of from 3 kW to 9 kW, which is pulsed in a range of from 25%-80% of the peak power at a frequency in a range of from 40 Hz to 270 Hz.

8. The method of claim 6, wherein the gas mixture in the substrate processing chamber is at a pressure in a range of from 0.1 Torr to 1.0 Torr.

9. The method of claim 1, wherein the gas mixture in the substrate processing chamber is at a pressure in a range of from 0.2 Torr to 0.8 Torr.

10. The method of claim 8, wherein the gas mixture in the substrate processing chamber is at a temperature in a range of from 450° C. to 600° C.

11. The method of claim 1, wherein the gas mixture in the substrate processing chamber is at a temperature in a range of from 500° C. 550° C.

12. The method of claim 1, wherein the roughness of the nanocrystalline diamond layer is less than 25 nm rms.

13. The method of claim 1, wherein the roughness of the nanocrystalline diamond layer is less than 10 nm rms.

14. The method of claim 12, wherein the nanocrystalline diamond layer comprises a single layer.

15. A method of depositing a diamond film on a surface of a substrate, the method comprising depositing a nanocrystalline diamond layer having a thickness, a roughness, a hardness, and a modulus using a microwave plasma enhanced chemical vapor deposition process, wherein the roughness is less than 25 nm rms, and the surface of the substrate does not include a nanocrystalline diamond layer under the nanocrystalline diamond layer formed using the microwave plasma enhanced chemical vapor deposition process.

16. The method of claim 15, wherein the roughness is less than 10 nm rms.

17. The method of claim 15, wherein depositing the nanocrystalline diamond layer comprises generating a pulsed microwave plasma in a gas mixture in a substrate processing chamber, the gas mixture comprising a first gas comprising H₂, a second gas comprising CO₂, a third gas selected from the group consisting of CH₄, C₂H₂, and C₂H₄, and a fourth gas comprising an inert gas selected from the group consisting of helium (He), nitrogen, (N₂), neon (Ne), argon (Ar), and combinations thereof.

18. The method of claim 17, wherein the gas mixture comprises
H₂ in a range of from 10 vol. % to 90 vol. %;
the third gas and the fourth gas together in a range of from 2 vol. % to 10 vol. %; and
argon in a range of from 10 vol. % to 90 vol. %.

19. The method of claim 18, wherein generating the microwave pulsed plasma in the gas mixture in the substrate processing chamber is generated at a peak power in a range of from 2,000 W to 12,000 W, which is pulsed in a range of from 10% to 90% of the peak power at a frequency in a range of from 10 Hz to 300 Hz.

20. A non-transitory computer readable medium including instructions, that, when executed by a controller of a substrate processing chamber, causes a substrate processing chamber deposit a diamond layer on a substrate by a method comprising generating a pulsed microwave plasma in a gas mixture in the substrate processing chamber, the gas mixture comprising a first gas comprising H₂ in a range of from 10 vol. % to 90 vol. %, a second gas comprising CO₂, a third gas selected from the group consisting of CH₄, C₂H₂, and C₂H₄, and a fourth gas comprising an inert gas selected from the group consisting of helium (He), nitrogen, (N₂), neon (Ne), argon (Ar), and combinations thereof in a range of from 10 vol. % to 90 vol. %, the third gas and the second gas together in a range of from 2 vol. % to 10 vol. %; and depositing a nanocrystalline diamond layer on the substrate.
